(19) United States
(12) Patent Application Publication
(10) Pub. No.: US 2022/0302358 A1
(43) Pub. Date: Sep. 22, 2022

(54) LIGHT EMITTING DEVICE AND DISPLAY DEVICE

(71) Applicant: Japan Display Inc., Tokyo (JP)

(72) Inventor: Masanobu IKEDA, Tokyo (JP)

(73) Assignee: Japan Display Inc., Tokyo (JP)

(21) Appl. No.: 17/832,693

(22) Filed: Jun. 6, 2022

Related U.S. Application Data
(63) Continuation of application No. PCT/JP2020/038157, filed on Oct. 8, 2020.

(30) Foreign Application Priority Data
Dec. 6, 2019 (JP) 2019-221537

(51) Int. Cl. H01L 33/54; H01L 27/15

(52) U.S. Cl. CPC H01L 33/54; H01L 27/156

(57) ABSTRACT

A light emitting device according to one embodiment includes a substrate including a mounting area, a plurality of light emitting elements disposed in the mounting area, and a sealing layer covering the light emitting elements and the mounting area. The sealing layer contains, a base material and a filler added to the base material. A coefficient of thermal expansion of the filler is smaller than the coefficient of thermal expansion of the base metal. Furthermore, a refractive index of the filler is different from the refractive index of the base material.

### CROSS-REFERENCE TO RELATED APPLICATIONS

This application is a Continuation Application of PCT Application No. PCT/JP2020/038157 filed Oct. 8, 2020 and based upon and claiming the benefit of priority from Japanese Patent Application No. 2019-221537, filed Dec. 6, 2019, the entire contents of all of which are incorporated herein by reference.

### FIELD

Embodiments described herein relate generally to a light emitting device and a display device.

### BACKGROUND

A light emitting device in which a plurality of small light emitting diodes (LEDs) are arrayed in a matrix on a substrate is known. For example, this type of light emitting device is assumed to be used as a backlight of a liquid crystal display device. In this application, the image contrast can be increased by local dimming in which a plurality of LEDs are partially turned on.

In the light emitting device as described above, a radical difference in luminance may occur between a lighting portion in which the LED emits light and a non-lighting portion in which the LED is turned off. In this case, smooth images may not be displayed. A diffusion film facing each of the LEDs to reduce the difference in luminance may be disposed but, in this case, the light emitting device is designed to be thick.

In addition, in a conventional light emitting device, the adherence between the substrate and the LEDs may not be able to be sufficiently secured, and there is room for improvement from the viewpoint of connection reliability, for the LED peeling off from the substrate doe to deformation caused by thermal stress.

### BRIEF DESCRIPTION OF THE DRAWINGS

FIG. 1 is a plan view showing a schematic configuration of a display device according to a first embodiment.

FIG. 2 is a schematic exploded perspective view showing the light emitting device according to the first embodiments.

FIG. 3 is a schematic plan view showing the light emitting device according to the first embodiment.

FIG. 4 is an enlarged schematic plan view showing the light emitting device shown in FIG. 3.

FIG. 5 is a schematic cross-sectional view showing the display device according to the first embodiment.

FIG. 6 is an enlarged schematic cross-sectional view showing a part of the light emitting device according to the first embodiment.

FIG. 7 is a table shewing results of evaluating boundary visibility and connection reliability.

FIG. 8 is a schematic cross-sectional view showing a display device according to a comparative example.

FIG. 9 is a schematic plan view showing a display device according to a second embodiment.

FIG. 10 is a flowchart showing a part of a manufacturing process of a light emitting device according to the second embodiment.

FIG. 11 is a schematic plan view showing a display

device according to a third embodiment.

FIG. 12 is a flowchart showing a part of a manufacturing process of a light emitting device according to a fourth embodiment.

FIG. 13 is a schematic cross-sectional view showing a display device according to the fourth embodiment.

FIG. 14 is a schematic cross-sectional view showing a display device according to a fifth embodiment.

FIG. 15 is a schematic cross-sectional view showing a display device according to a sixth embodiment.

### DETAILED DESCRIPTION

In general, according to one embodiment, a light emitting device includes a substrate including a mounting area, a plurality of light emitting elements disposed in the mounting area, and a sealing layer covering the light emitting elements and the mounting area. The sealing layer contains a base material and a filler added to the base material. A coefficient of thermal expansion of the filler is smaller than the coefficient of thermal expansion of the base metal. Furthermore, a refractive index of the filler is different from the refractive index of the base material.

According to the above structure, a light emitting device and a display device, having excellent lighting and display quality and improved reliability, can be provided.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter oi course. However, such schematic illustration is merely exemplary, and in no way restricts the interpretation of the invention. In the drawings, reference numbers of continuously arranged elements equivalent or similar to each other are omitted in some cases. In addition, in the specification and drawings, structural elements which function in the same or a similar manner to those described in connection with preceding drawings are denoted by like reference numbers, detailed description thereof being omitted unless necessary.

In the first to fifth embodiments, a transmissive liquid crystal display device is disclosed as an example of the display device. In addition, a backlight of the liquid crystal display device is disclosed as an example of a light emitting device in these embodiments. furthermore, a self-luminous display device (light emitting device) is disclosed in the sixth embodiment. Each of the embodiments does not prevent application of individual technical ideas disclosed in each embodiment to other types of display devices and light emitting devices.

As the other types of display devices, for example, anti-transmissive liquid crystal display devices, display devices to which micro-electromechanical systems (MEMS) are applied, and the like, which require separate light sources, are assumed. In addition, for example, a device that illuminates a room, a showcase, or the like are assumed as the other type of the light emitting device. For this reason, the light emitting device may be restated as an illumination device.

### First Embodiment

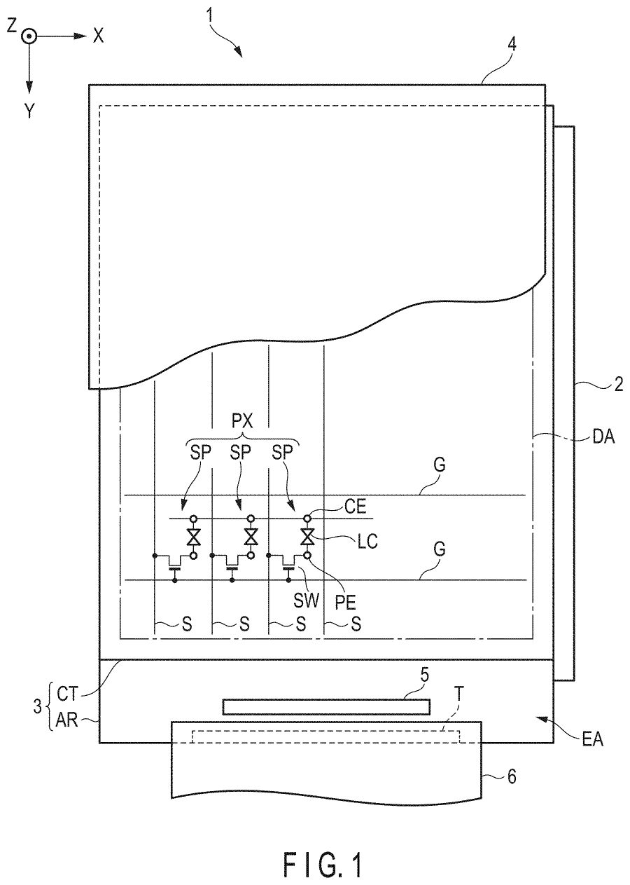

FIG. 1 is a plan view showing a schematic configuration of a display device 1 according to a first embodiment. In the figure, an X direction, a Y direction, and a Z direction are orthogonal to each other.

The display device 1 comprises a light emitting device 2 which is a backlight, a display panel 3 which is a liquid crystal display cell, a cover member 4, a display controller 5, and a wiring board 6. In FIG. 1, the stacked laminated light emitting device 2, display panel 3, and cover member 4 are slightly shifted in the X direction and the Y direction for convenience of explanation.

The display panel 3 comprises an array substrate AR, a counter-substrate CT opposed to the array substrate AR, and a liquid crystal layer LC sealed between the array substrate AP and the counter-substrate CT. Furthermore, the display panel 3 includes a display area DA at a portion where the array substrate AR and the counter-substrate CT overlap.

In the display ares DA, the array substrate AR comprises a plurality of scanning lines G and a plurality of signal lines S. The plurality of scanning lines G extend in the X direction and are arranged in the Y direction. The plurality of signal lines S extend in the Y direction and are arranged in the X direction.

The display area DA includes a plurality of pixels PX arrayed in a matrix. The pixel PX includes a plurality of sub-pixels SP corresponding to different colors. For example, the pixel PX includes red, green, and blue sub-pixels SP, but the pixel PX may include the sub-pixels SP of the other color such as white.

The array substrate AR comprises pixel electrodes PE and switching elements SW arranged in the respective sub-pixels SP. Furthermore, the array substrate AR comprises common electrodes CE extending over the plurality of sub-pixels SP. A common voltage is applied to the common electrodes CE.

In the example of FIG. 1, the array substrate AR includes an extension area EA extending from an end portion of the counter-substrate CT, which is on a lower side in the figure. The display controller 5 is mounted in the extension area EA. The extension area EA includes a terminal portion T for external connection. The wiring board 6 is connected to the terminal portion T. The wiring board 6 inputs signals related to image display to the display panel 3. The display controller 5 controls a voltage of each pixel electrode PE, based on this signal.

The light emitting device 2 is opposed to a back surface of the array substrate AR. The cover member 4 is formed of, for example, glass, and covers the display area DA.

The light emitting device 2, the display panel 3, and the cover member 4 have a rectangular shape in the example of FIG. 1. However, the shape of the light emitting device 2, the display panel 3, and the cover member 4 is not limited to this example, and may be a circular shape or other polygonal shapes.

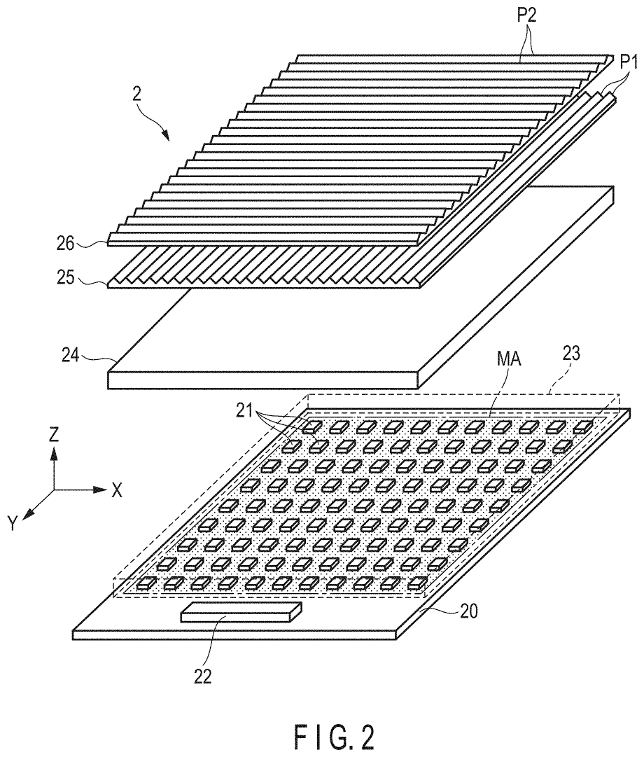

FIG. 2 is a schematic exploded perspective view showing the light emitting device 2. The light emitting device 2 according to this embodiment comprises a substrate 20, a plurality of LED elements 21, a Light emission controller 22, a sealing layer 23, a wavelength conversion film 24, a first prism sheet 25, and a second prism sheet 26. The LED element 21 is an example of the light emitting element. The wavelength conversion film 24, the first prism sheet 25, and the second prism sheet 26 are examples of optical films.

The substrate 20 is, for example, a flexible printed circuit board (FPC). The substrate 20 may be a printed circuit board having higher rigidity than the flexible printed circuit board.

The substrate 20 has a mounting area MA (light emitting area). The mounting area MA is opposed to the above-described display area DA. The plurality of LED elements 21 are mounted in the mounting area MA. A method of mounting the LED elements 21 on the substrate 20 is not particularly limited but, for example, flip-chip bonding can be employed. In flip-chip bonding, the LED elements 21 and the conductive layer of the substrate 20 are connected via a conductive material (bump) such as solder, gold, or an anisotropic conductive film.

The LED element 21 is, for example, a mini LED having a rectangular shape in planar view with a longest side having a length of more than 100 μm and less than 300 μm. The LED element 21 may be a micro LED with the longest side having a length of 100 μm or less. Alternatively, the LED element 21 may be an LED with the longest side having a length of 300 μm or more.

The light emission controller 22 is an IC mounted on the surface of the substrate 20 outside the mounting area MA, for example, as in the example of FIG. 2. However, the light emission controller 22 may be mounted on a wiring board or the like connected to the substrate 20. The light emission controller 22 and each LED element 21 are connected by wires formed on the substrate 20. The light emission controller 22 turns on and off each of the LED elements 21.

The sealing layer 23 is formed on the surface of the substrate 20 and covers each of the LED elements 21. In the example of FIG. 2, the sealing layer 23 is formed to cover the entire mounting area MA, and the light emission controller 22 is exposed from the sealing layer 23. However, the range of forming the sealing layer 23 is not limited to this example, and the layer may cover a wider range of the surface of the substrate 20. The sealing layer 23 desirably does not absorb the light emitted by the LED elements 21 as much as possible or does not convert the wavelength of the light.

The wavelength conversion film 24 is opposed to the mounting area MA and the sealing layer 23. The wavelength conversion film 24 has a size that overlaps with at least the entire mounting area MA. The wavelength conversion film 24 converts the wavelength of the light emitted by the LED elements 21. A quantum dot film can be used as such a wavelength conversion film. The quantum dot film includes a plurality of quantum dots that absorb the light emitted by the LED elements 21 and emit light having a longer wavelength.

For example, the LED element 21 emits blue light having a peak wavelength of less than 500 nm, and the wavelength conversion film 24 absorbs the blue light and emits light having a peak wavelength of 500 nm or more. However, the wavelengths of the light emitted by the LED element 21 and the light converted by the wavelength conversion film 24 are not limited to this example.

The first prism sheet 25 includes a plurality of prisms P1 that are arranged in the X direction and extend parallel to the Y direction. The second prism sheet 26 includes a plurality of prisms P2 that are arranged in the Y direction and extend parallel to the X direction. The second prism sheet 26 is opposed to a back surface of the display panel 3 shown in FIG. 1. The first prism sheet 25 and the second prism sheet 26 collect the light emitted by the wavelength conversion film 24. The image luminance is improved by the display panel 3 displaying the images using the light thus collected.

In the example of FIG. 2, the first prism sheet 25 is located between the wavelength conversion film 24 and the second prism sheet 26, but the second prism sheet 26 may be located between the wavelength conversion film 24 and the first prism sheet 25. Alternatively, the directions in which the prisms P1 and P2 extend may be tilted with respect to the X direction and the Y direction.

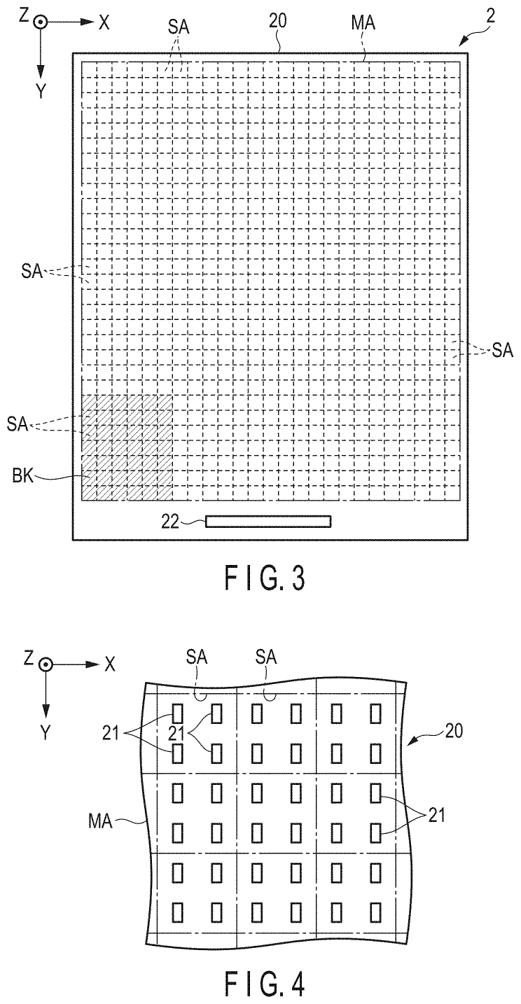

FIG. 3 is a schematic plan view showing the light emitting device 2. The substrate 20 and the light emission controller 22 of the light emitting device 2 are shown in this figure.

As shown in FIG. 3, the mounting area MA has a plurality of segment areas SA. The plurality of LED elements 21 are arranged in each of the segment areas SA. The segment area SA constitutes a unit for driving the LED elements 21. In other words, the plurality of LED elements 21 disposed in the mounting area MA are turned on or off for each segment area SA under the control of the light emission controller 22. In the example of FIG. 3, the segment areas SA are arrayed in a matrix in the X direction and the Y direction.

The light emitting device 2 having such a configuration can execute local dimming in which a plurality of LED elements 21 are partially turned on. For example, when a high-luminance image opposed to a block BK shown in FIG. 3 is displayed in the above-described display area DA, the LED elements 21 of the segment areas SA included in the block BK are turned on and the other LSD elements 21 are turned off. Contrast of the image displayed in the display area DA can be thereby increased.

The mounting area MA may be divided into a plurality of blocks BK in advance and local dimming may be executed in units of these blocks BK. Alternatively, the block BK may be dynamically set according to the data of the displayed images.

FIG. 4 is an enclosed schematic plan view showing a part of the light emitting device 2 shown in FIG. 3. A plurality of LSD elements 21 disposed in the segment areas SA are shown in this figure.

In the example of FIG. 4, four LED elements 21 are disposed in one segment, area SA. For example, the four LED elements 21 disposed in one segment area SA are connected in series. The LED elements 21 disposed in different segment areas SA are isolated from each other.

For example, the LED element 21 has a rectangular shape in planar view as shown In FIG. 4. However, the LED element 21 may have the other shape such as a square. In the example of FIG. 4, each pitch of the LED elements 21 in the X direction is constant and the pitch in the Y direction is also constant. However, these pitches may be partially different.

The number of LED elements 21 disposed in one segment area 3A is not limited to four, but may be three or less and five or more. The shape of the segment area SA is not limited to the example of the square shown in FIG. 3 and FIG. 4, but may be a shape elongated in the X direction or the Y direction.

The substrate 20 may be composed of a plurality of substrate pieces. For example, the substrate 20 may be composed of a plurality of substrate pieces that are elongated in the X direction and arranged in the Y direction. Alternatively, the substrate 20 may be composed of a plurality of substrate pieces that are elongated in the Y direction and arranged in the X direction. Furthermore, the substrate 20 may be composed of substrate pieces arranged in m×n (m, n≥2) in the X direction and the Y direction. In these cases, the mounting area MA is composed of the surfaces of the plurality of substrate pieces.

FIG. 5 is a schematic cross-sectional view showing the display device 1. The elements of the light emitting device 2 and the display panel 3 described so far, that is, the substrate 20, the sealing layer 23, the wavelength conversion film 24, the first prism sheet 25, the second prism sheet 26, the array substrate AR, the counter-substrate CT, and the cover member 4 are stacked in the Z direction.

In this embodiment, the sealing layer 23 and the wavelength conversion film 24 are bonded by a first adhesive layer AD1. In addition, the display panel 3 and the cover member 4 are bonded by a second adhesive layer AD2.

The first adhesive layer AD 1and the second adhesive layer AD2 are formed by, for example, optical clear adhesive (OCA). The first adhesive layer AD1 and the second adhesive layer AD2 may be formed by the other method such as optical clear resin (OCR).

Polarizers may be disposed between the array substrate AR and the light emitting device 2 and between the counter-substrate CT and the cover member 4, respectively. Alternatively, when an optical film other than the wavelength conversion film 24 is disposed directly above the sealing layer 23, the sealing layer 23 may be bonded to the optical film by the first adhesive layer AD1.

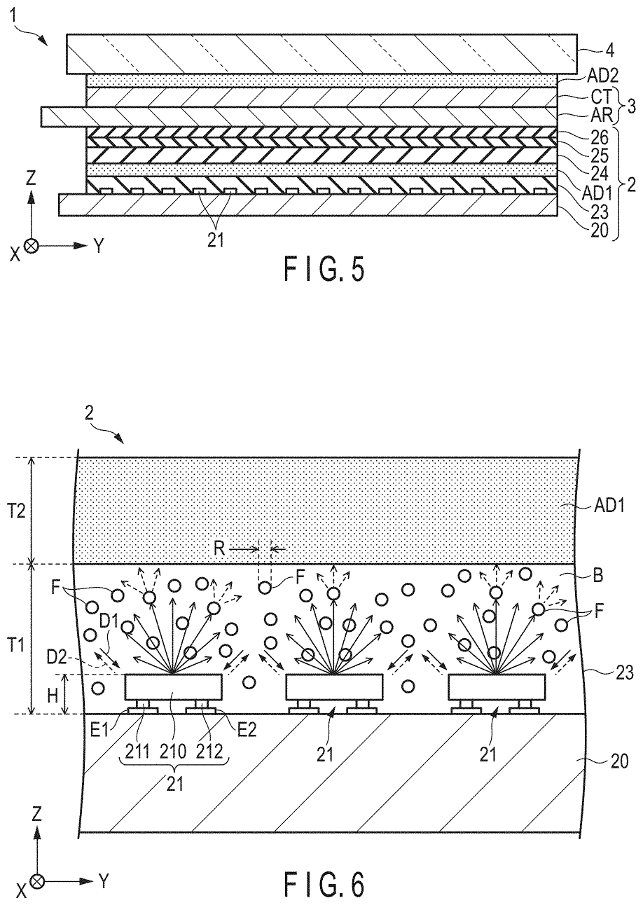

FIG. 6 is an enlarged schematic cross-sectional view showing a part of the light emitting device 2. The substrate 20, the LED elements 21, the sealing layer 23, and the first adhesive layer AD1 are shown in this figure.

The substrate 20 comprises a first electrode E1 and a second electrode E2 at a position where each LED element 21 is disposed. The LED element 21 comprises an LED substrate 210, a first pad 211, and a second pad 212.

The first pad 211 and the second pad 212 are provided on a bottom surface of the LED substrate 210 opposed to the substrata 20. The first pad 211 is connected to an anode formed in the LED substrate 210, and the second pad 212 is connected to a cathode formed in the LED substrate 210. The first pad 211 and the second pad 212 are connected to the first electrode E1 and the second electrode E2, respectively, by, for example, the above-mentioned flip chip bonding. When a potential difference is formed between the anode and the cathode of the LSD substrate 210 via the first electrode E1, the second electrode E2, the first pad 211, and the second pad 212, the LED substrate 210 emits light having an intensity peak in the Z direction. This light is, for example, diffused light that spreads as it travels in the Z direction.

The sealing layer 23 covers the entire LED element 21 and is also in contact with the surface of the substrate 20. From the viewpoint of sufficiently protecting the LED element 21, a thickness T1 of the sealing layer 23 is desirably twice or more as large as a height H of the LED element 21 from the surface of the substrate 20. For example, the height H of the LED element 21 is 100 μm, and the thickness T1 of the sealing layer 23 is 200 μm or more and 300 μm or less. In addition, a thickness T2 of the first adhesive layer AD1 is, for example, 75 μm or more and 100 μm or less.

In this embodiment, the sealing layer 23 contains a base material 5 and a large number of fillers F added to the base material B. The base material B and the fillers F are formed of materials having high translucency and having different coefficients of thermal expansion and refractive indices. More specifically, the coefficient of thermal expansion of the fillers F is smaller than the coefficient, of thermal expansion of the base material B. For example, a diameter R of the fillers F is 100 nm or more and 10 μm or less.

As the base material 3, fox example, an epoxy resin having the coefficient of thermal expansion (CTE) of approximately 65×10\hat{ }-6 [1/K], an acrylic resin having the coefficient of thermal expansion of approximately 75×10\hat{ }-6 [1/K], or a silicone resin having the coefficient of thermal expansion of approximately 300×10\hat{ }-6 [1/K] can be used.

In addition, the fillers F are desirably formed of a material having a negative coefficient of thermal expansion. Examples of the material having a negative coefficient, of thermal expansion include ZrW₂O₈ having the coefficient of thermal expansion of approximately −8.7×10\hat{ }-6 [1/K], Ca₂RuO₄ having the coefficient of thermal expansion of −115×10\hat{ }-6 [1/K], Lu₂W₃O₁₂ having the coefficient of thermal expansion of approximately −6.8×10\hat{ }-6 [1/K], and Mn₃XN (X: Cu—Sn, Zn—Sn) having the coefficient of thermal expansion of approximately −30×10\hat{ }-6 [1/K].

Even when any one of materials of the base material B and the fillers F exemplified here is selected, the coefficient of thermal expansion of the fillers F is smaller than the coefficient of thermal, expansion of the base material 8. Furthermore, the refractive indices of the fillers F and the base material 8 are also different from each other.

The sealing layer 23 also plays a role of fixing the LED elements 21 to the surface of the substrate 20. In other words, when the sealing layer 23 to be cured is applied to the surface of the substrate 20, and heated and cross-linked, at the time of manufacturing the light emitting device 2, the sealing layer 23 shrinks toward the shrinkage direction D1 shown in FIG. 6. As a result, the LED elements 21 are pushed toward the substrate 20, and the LED elements 21 and the substrate 20 are firmly connected.

In contrast, when the temperature of the sealing layer 23 rises in the light emitting device 2 after manufacturing, the sealing layer 23 greatly expands toward an expansion direction D2 opposite to the shrinkage direction D1 in a case where the fillers F are not added. If the shearing stress generated by this expansion is large, the LSD elements 21 can be peeled off from the substrate 20.

In this respect, if the fillers F formed of a material having the coefficient of thermal expansion smaller than that of. the base material B, preferably a material having a negative coefficient of thermal expansion are added to the sealing layer 23, similarly to this embodiment, a composite coefficient of thermal expansion of the sealing layer 23 can be lowered. In this case, the thermal expansion of the sealing layer 23 becomes also relatively small, the peeling of the LED elements 21 is suppressed, and the connection reliability is improved.

In addition, if the refractive indices of the base material B and the fillers F are different, it is advantageous from the viewpoint of illumination (light emission) and display quality. In other words, the light emitted by the LED elements 21 is scattered in the sealing layer 23 since the light is refracted at the boundary between the fillers F and the base material B. As a result, since the upper display panel 3 is irradiated with uniform light, non-uniformity in luminance in the display area DA is suppressed. In addition, when the above-mentioned local dimming is executed, the decrease in brightness becomes gentle from the block in which the LED elements 21 are turned on toward its periphery. Therefore, it is possible to prevent the boundary of the block from being visually recognized as an unnatural pattern.

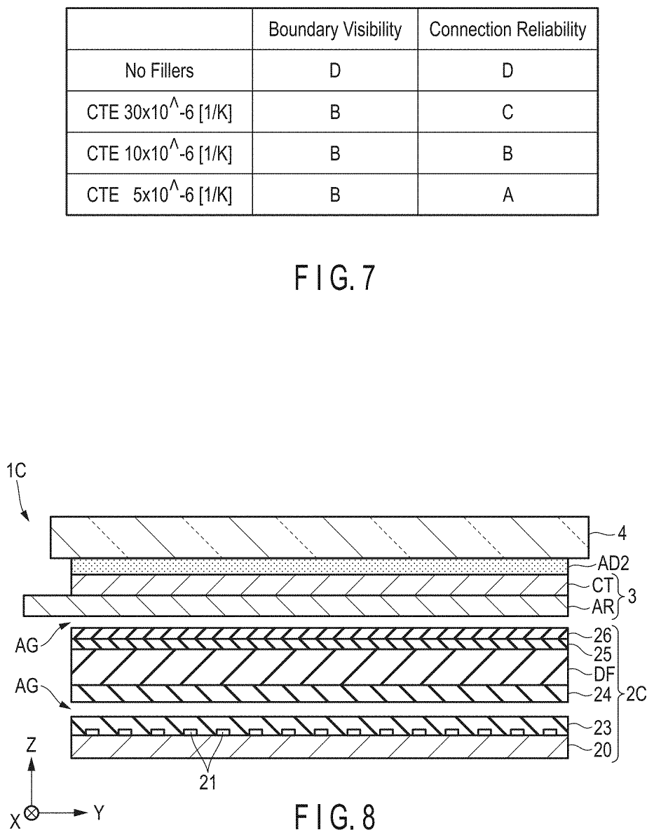

FIG. 7 is a table shewing results of evaluating boundary visibility of the illumination block at the time of local dimming and connection reliability between the LED elements 21 and the substrate 20. The evaluation was executed in four patterns that the fillers F were not added to the sealing layer 23, and the composite coefficient of thermal expansion of the sealing layer 23 was lowered to 30×10\hat{ }-6 [1/K], 10×10\hat{ }-6 [1/K], and 5×10\hat{ }-6 [1/K]by adding the fillers F. Evaluation levels A to D indicate that A is the best and D is the worst.

When the fillers F were not added, the evaluation levels of the boundary visibility and the connection reliability were both D. When the composite coefficient of thermal expansion of the sealing layer 23 was 30×10\hat{ }-6 [1/K], the evaluation level of the boundary visibility was improved to B and the evaluation level of the connection reliability was improved to C.

When the composite coefficient of thermal expansion of the sealing layer 23 was 10×10\hat{ }-6 [1/K], the connection reliability was further Improved and the evaluation level was B. When the composite coefficient of thermal expansion of the sealing layer 23 was 5×10\hat{ }-6 [1/K], the evaluation level of the connection reliability reached A.

As can be understood from the above evaluation results, if the fillers F are added to the sealing layer 23 to lower the composite coefficient of thermal expansion, both the boundary visibility and the connection reliability are improved. If the composite coefficient of thermal expansion of the sealing layer 23 is 10×10\hat{ }-6 [1/K] or less, both the boundary visibility and the connection reliability become desirable while, if the composite coefficient of thermal expansion is 5×10\hat{ }-6 [1/K] or less, the connection reliability can be further improved. For example, when the base material B is an epoxy resin and the material of the fillers F is ZrW₂O₈, the ratio of the fillers F to the total volume of the sealing layer 23 may be adjusted to 10% to realise the sealing layer 23 having the coefficient of thermal expansion of 10×10\hat{ }-6 [1/K]. The refractive index of the epoxy resin is 1.55 to 1.61, and the refractive index of ZrW₂O₈ is 1.39. For this reason, since a sufficient difference in refractive index is generated between the base material B and the fillers F, the light emitted by the LSD elements 21 is also desirably scattered.

Further advantages of this embodiment will be described with reference to a comparative example.

FIG. 8 is a schematic cross-sectional view showing a display device 1C according to the comparative example of this embodiment. The display device 1C comprises a light emitting device 2C. Similarly to the light emitting device 2 according to this embodiment, the light emitting device 2C comprises a substrate 20, LED elements 21, a sealing layer 23, a wavelength conversion film 24, a first prism sheet 25, and a second prism sheet 26. However, fillers F are not added to the sealing layer 23 of the light emitting device 2C. In this case, since the light emitted by the LED elements 21 needs to be diffused before reaching the display panel 3, the diffusion layer DF is disposed between the wavelength conversion film 24 and the first prism sheet 21. The diffusion layer DF is constituted by stacking, for example, approzimately five diffusion films in the Z direction, and has a thickness of approximately 400 μm. Furthermore, in the display device 1C, air layers AG are provided between the sealing layer 23 and the wavelength conversion film 24, and between the second prism sheet 26 and the display panel 3, respectively.

If the heat generated when the LED elements 21 are turned on with high luminance or the heat generated when the display panel 3 is driven is transferred to the diffusion film DF, thermal stress (stress and temperature) may occur in the diffusion film DF. When the air layers AG are provided as shown in FIG. 8, the diffusion film DF is protected from the thermal stress by its heat insulation effect.

Since the thick diffusion layer DF and the two air layers AG are present in such a display device 1C, the thickness of the light emitting device 2C or the display device 1C increases. In addition, since the air layer AG is present directly above the sealing layer 23, the difference in refractive index at the interface above the sealing layer 23 is large. For this reason, the light emitted by the LED elements 21 can be reflected at the boundary between the sealing layer 23 and the air layer AG. As a result, since the amount of emission of the light emitted by the LED elements 21 is reduced, the output of the LED elements 21 needs to be increased to obtain a desired luminance.

In contrast, in the display device 1 according to this embodiment, since the light is diffused by the fillers F added to the sealing layer 23, the diffusion film does net necessarily have to be disposed. When the diffusion film is not disposed as shown in FIG. 5, the thermal stress on the film does not need to be considered and the air layers AG are therefore unnecessary. Since the thermal conductivity of the fillers F is higher that the thermal conductivity of the base material B, the heat generated by the LED elements 21 is more likely to escape to the substrate 20 side as compared with the example shown in FIG. 8.

If the diffusion layer DF or the two air layers AG are not provided, the thickness of the light emitting device 2 or the display device 1 can be reduced. Furthermore, when the scaling layer 23 is bonded to an optical film such as the wavelength conversion film 24 by the first adhesive layer AD1, the difference in refractive index at the interface above the sealing layer 23 becomes small. Thus, since the light emitted by the LED elements 21 is less likely to be reflected at the interface, the light utilization efficiency is improved. As a result, the power consumption of the light emitting device 2 can be reduced.

Besides the above, various desirable advantages can be obtained from this embodiment.

### Second Embodiment

The second embodiment will be described. The same configuration as that of the first embodiment can be applied to portions that are not particularly mentioned in this embodiment.

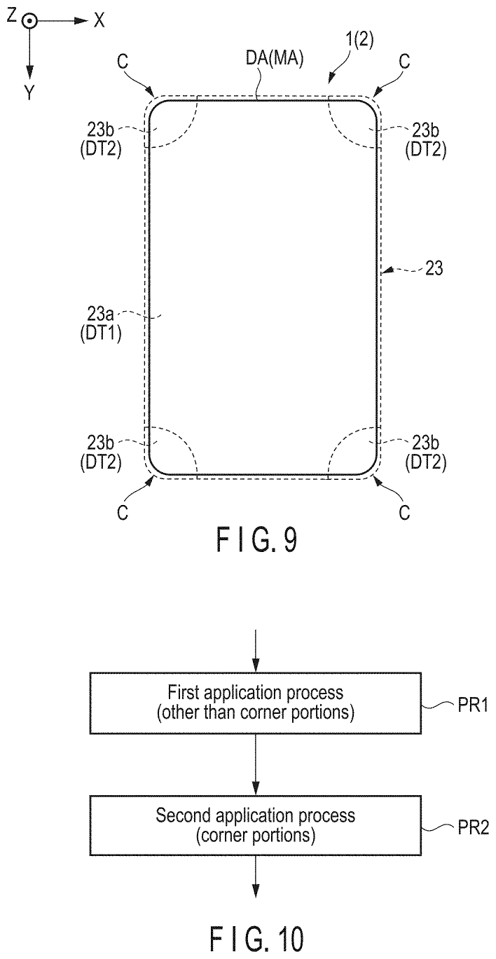

FIG. 9 is a schematic plan view showing a display device 1 according to this embodiment. A display area DA, a mounting area MA, and a sealing layer 23 are shown in this figure. For example, outer edge shapes of the display area DA and the mounting area MA correspond to each other. However, the mounting area MA may be larger than the display area DA.

In the example of FIG. 9, the outer edge shape of the display area DA and the mounting area MA includes four corner portions C rounded in an arc shape. The sealing layer 23 includes a first portion 23a and four second portions 23b . The first portion 23a covers an area of the mounting area MA excluding vicinities of the four corner portions C. Each of the second portions 23b covers a portion which is not covered with the first portion 23a, .i.e., an area of the mounting area MA including the corner portion C.

The same fillers F as those of the first embodiment are added to both the first portion 23a and the second portions 23b . In this embodiment, a density DT2 of the fillers F in the second portions 23b is higher than a density DT1 of the fillers F in the first portion 23a (D72>DT1). These densities DT1 and DT2 are the volume densities of the fillers F in the first portion 23a and the second portions 23b.

FIG. 10 is a flowchart showing a part of the manufacturing process of the light emitting device 2. The sealing layer 23 shown in FIG. 9 is formed through a first application process PR1 and a second application process PR2.

In the first application process PR1, a material formed by adding the fillers F to the base material 8 to be cured, at the density DT1 is applied to the area excluding the vicinities of the corner portions C of the mounting area MA. The application of the material can be executed by, for example, an ink-jet method, but is not limited to this example.

In the subsequent second application process FP2, a material formed by adding the fillers F to the base material 8 to be cured, at the density DT2 is applied to the vicinities of the corner portions C of the mounting area MA. This application can also be executed by, for example, an ink-jet method.

The sealing layer 23 including the first portion 23a to which the fillers F are added at the density DT1 and the four second portions 23b to which the fillers F are added at the density DT2, is formed by curing the material thus applied.

The number of LED elements 21 that illuminate the display area DA is relatively smaller as compared with the other areas, at the corner portions C of the mounting area MA. For this reason, the image luminance in the vicinities of the corner portions C can be lowered. In contrast, if the density of the fillers F is increased in the vicinities of the corner portions C similarly to this embodiment, the light from the LED elements 21 is suitably scattered, and the image luminance in the vicinities of the corner portions C can be increased to the same level as that in the other areas.

In this embodiment, an example in which the densities of the fillers F contained in the first portion 23a and the second portion 23b are different has been disclosed. As the other example, the fillers F contained in the second portions 23b may be formed of a material having a larger difference in refractive index from the base material B than the fillers F contained in the first portion 23a . Even in this case, the light from the LED elements 21 is suitably scattered in the second portions 23b, and the the image luminance in the vicinities of the corner portions C can be increased to the same level as that in the other areas. The coefficients of thermal expansion of. the fillers F contained m the first portion 23a and the second portions 23b may be different from each other.

### Third Embodiment

A third embodiment will be described. The same configuration as that of each of the above-described embodiments can be applied to portions that are not particularly mentioned in this embodiment.

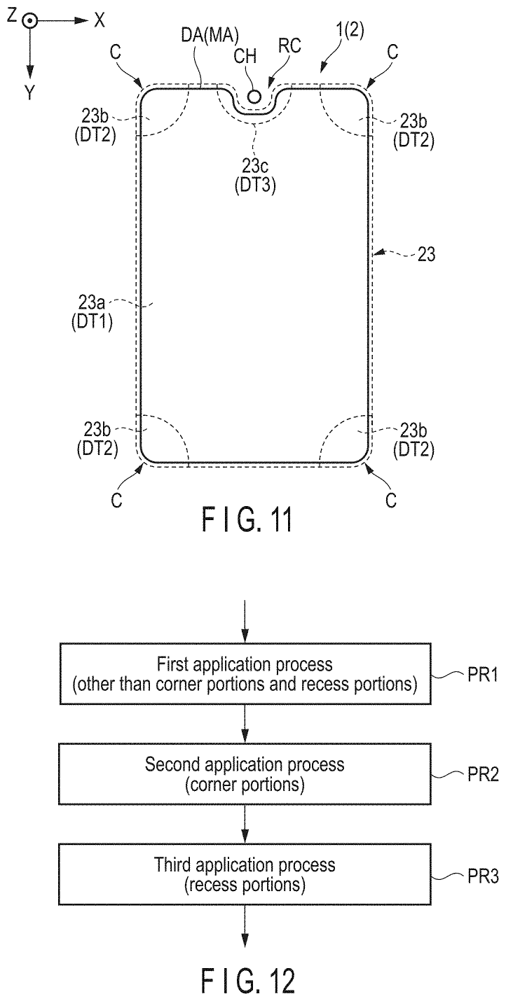

FIG. 11 is a schematic plan view showing a display device 1 according to this embodiment. A display area DA, a mounting area MA, and a sealing layer 23 are shown in this figure, similarly to FIG. 3.

In this embodiment, the outer edge shape of the display area DA and the mounting area MA includes a recess portion RC. For example, a camera hole CH in which a lens of a camera module is arranged is provided in a recess portion RC.

The sealing layer 23 includes a third portion 23c in addition to the above-mentioned first portion 23a arid second portions 23b . The third portion 23c covers an area in the mounting area MA, which includes the recess portion RC.

In this embodiment, a density DT3 (volume density) of the fillers F in the third portions 23c is higher than the density DT1 of the fillers F in the first portion 23a (DT3>DT1). The density DT3 may be the same as or different from the density DT2 of the second portions 23b.

FIG. 12 is a flowchart showing a part of the manufacturing process of the light emitting device 2. The sealing layer 23 shown in FIG. 11 is formed through a first application process PR1, a second application process PR2, and a third application process PR3.

In the first application process PR1, a material formed by adding the fillers F to the base material B to be cured, at the density DT1, is applied to the area in the mounting area MA excluding the vicinities of the corner portions C and the vicinity of the recess portion RC. In the subsequent second application process PR2, a material formed by adding the fillers F to the base material B to be cured, at the density DT2 is applied to the vicinities of the corner portions C of the mounting area MA.

In the subsequent third application process PR3, a material formed by adding the fillers F to the base material B to be cured, at the density DT3, is applied to the vicinity of the recess portion RC in the mounting area MA. The application in each of the application processes PR1 to PR3 can be executed by, for example, an ink-jet method, but is not limited to this example.

The sealing layer 23 including the first portion 23a to which the fillers f are added at the density DT1, the four second portions 23b to which the fillers F are added at the density DT2, and the third portion 23C to which the fillers F are added at the density DT3, is formed by curing the material thus applied.

In the recess portion RC the mounting area MA, too, similarly to the corner portions C, the number of LED elements 21 that illuminate the display area DA is relatively smaller as compared with that in the other areas. For this reason, the image luminance in the vicinity of the corner portion C can be lowered. In contrast, if the density of the fillers F is increased in the vicinity of the recess portion RC similarly to this embodiment, the light from the LED elements 21 is suitably scattered, and the image luminance in the vicinity of the recess portion RC can be increased to the same level as that in the other areas.

In this embodiment, an example in which the densities of the fillers F contained in the first portion 23a and the second portions 23b are different has been disclosed. As the other example, the fillers F contained in the third portion 23c may be formed of a material having a larger difference in refractive index from the base material 2 than the fillers F contained in the first portion 23a . Even in this case, the light from the LED elements 21 is suitably scattered in the third portion 23c , and the image luminance in the vicinity of the recess portion RC can be increased to the same level as that in the other areas. The coefficients of thermal expansion of the fillers F contained in the first portion 23a and the third portion 23c may be different from each other.

### Fourth Embodiment

A fourth embodiment will be described. The same configuration as that of each of the above-described embodiments can be applied to portions that are not particularly mentioned in this embodiment.

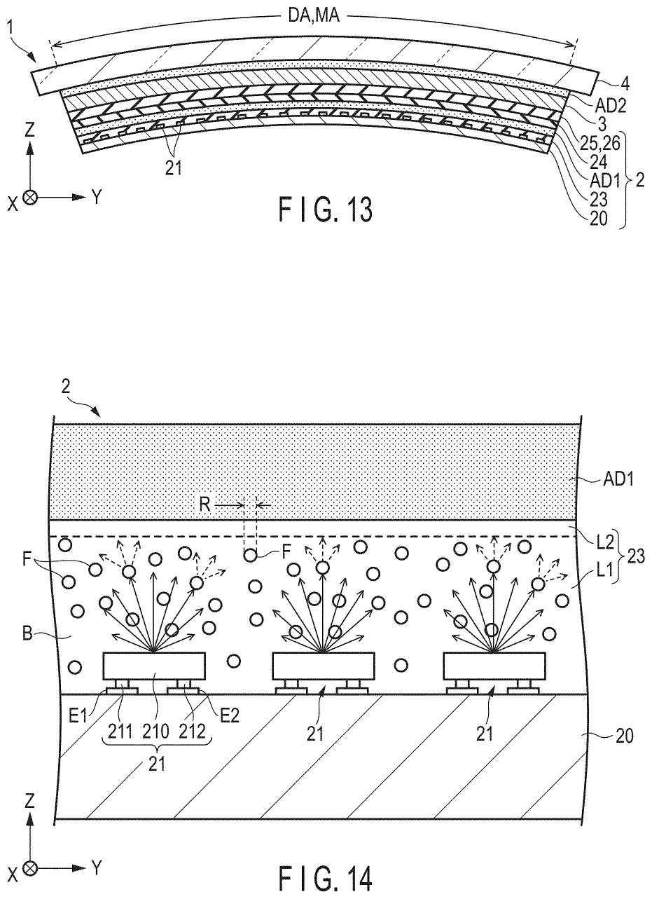

FIG. 13 is a schematic plan view showing a display device 1 according to this embodiment. A stacked structure of a light emitting device 2, a display panel 3, and a cover member 4 is the same as that of the first embodiment.

In this embodiment, the light emitting device 2, the display panel 3, and the cover member 4 are bent. In the example shown in FIG. 13, the display device 1 is bent as a whole about an axis parallel to the X direction. In this case, both a mounting area MA and a display area DA have curvatures. The manner of bending the display device 1 is not limited to the example shown in FIG. 13. For example, both end portions of the display device 1 in the Y direction may be bent, and a central portion of the display device 1 in the Y direction may be flat.

To bend the display device 1 in this manner, the light emitting device 2 and the display panel 3 have flexibility. If a flexible printed circuit board is used as a substrate 20 as described above, the light emitting device 2 having flexibility can be realized. In addition, if bases of an array substrate AR and a counter-substrate CT are formed of a resin substrate such as polyimide, the display panel 3 having flexibility can be realized. The cover member 4 may be formed of a flexible material or may be formed in a pre-bent shape by a rigid material.

If an air layer AG is present similarly to the display device 1C shown in FIG. 6, the distance from each LED element 21 to the display panel 3 may be varied when the display device 10 is bent. In this case, the luminance of the light emitted from a light emitting device 20 to the display panel 3 may not be uniform.

In contrast, in this embodiment, a sealing layer 23 and a wavelength conversion film 24 are bonded by a first adhesive layer AD1. In addition, the light emitting device 2 and the display panel 3 are in close contact with each other. Since the air layer AG is not present in such a structure, the distance from each LED element 21 to the display panel 3 becomes constant as a whole even when the display device 1 is bent. As a result, the luminance of the light emitted from the light emitting device 2 to the display panel 3 becomes uniform, and the display quality is improved.

### Fifth Embodiment

A fifth embodiment will be described. The same configuration as that of each of the above-described embodiments can be applied to portions that are not particularly mentioned in this embodiment.

FIG. 14 is a schematic cross-sectional view showing a light emitting device 2 according to this embodiment. The light emitting device 2 shown in this figure is different from the configuration shown in FIG. 6 in that the sealing layer 23 includes a first layer L1 and a second layer L2.

The first layer L1 covers surfaces of each LED element 21 and the substrate 20. The first layer L1 contains a base material B and a large number of fillers F. The second layer L2 covers the first layer L1. No fillers F are added to the second layer L2. The material of the second layer L2 is, for example, the same as the base material B of the first layer L1. However, the material of the second layer L2 may be formed of a material different from that of the base material B. The first adhesive layer ADI bonds the second layer L2 to an optical film (for example, a wavelength conversion film 2A) provided above the second layer L2.

When forming the sealing layer 23, the first layer L1 is first formed on the substrate 20. After that, the second layer L2 is formed on the first layer L1. A thickness of the second layer L2 is smaller than the thickness of the first layer L1. For example, the thickness of the second layer L2 is larger than the diameter R of the fillers F and is three times or less as large as the diameter R.

When the second layer L2 to which the fillers F are not added is provided above the sealing layer 23 similarly to this embodiment, the upper surface of the sealing layer 23 does not have irregularities due to the fillers F. For this reason, the upper surface of the sealing layer 23 can be smoothed.

### Sixth Embodiment

A sixth embodiment will be described. The same configuration as that of each of the above-described embodiments can be applied to portions that are not particularly mentioned in this embodiment.

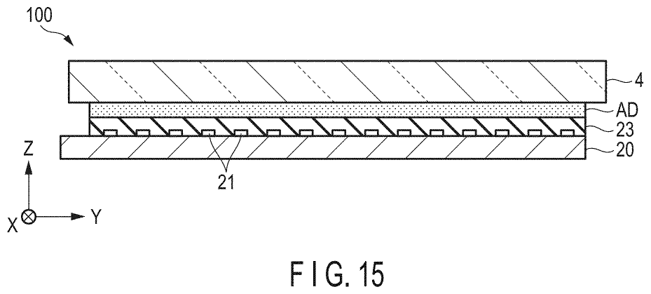

FIG. 15 is a schematic cross-sectional view showing a light emitting device 100 according to this embodiment. The light emitting device 100 comprises a substrate 20, a plurality of LED elements 21, and a sealing layer 23, similarly to the light emitting device 2 in each of the above-described embodiments. Furthermore, the light emitting device 100 comprises a cover member 4 and an adhesive layer AD. The adhesive layer AD bonds the sealing layer 23 to the cover member 4. The adhesive layer AD can be formed by, for example, a method such as OCA or OCR.

In this embodiment, each LED element 21 functions as a sub-pixel. For example, one pixel is composed of LED elements 21 that emit red, green, and blue light. The substrate 20 comprises lines, a switching element (TFT), a driver circuit, and the like, for individually driving each LED element 21.

In such a configuration, an image can be displayed by turning on each LED element 21 according to the image data. In other words, the light emitting device 100 itself functions as a display device in this embodiment.

Each LED element 21 may emit light of the same color. In this case, sub-pixels of different colors may be realized by disposing a plurality of types of wavelength conversion films (for example, quantum dot films) with respect to a specific LED element 21.

When the light emitting device 100 itself functions as a display device similarly to this embodiment, the LED element 21 is desirably a micro LED. High-definition image display can be thereby executed.

All of the display devices that can be implemented by a person of ordinary skill in the art through arbitrary design changes to the display devices described above as embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A light emitting device comprising:
a substrate including a mounting area;
a plurality of light emitting elements disposed in the mounting area; and
a sealing layer covering the light emitting elements and the mounting area,
wherein
the sealing layer includes a base material and a filler contained in the base material,
a coefficient of thermal expansion of the filler is smaller than a coefficient of thermal expansion of the base material,
a refractive index of the filler is different from a refractive index of the base material.

2. The light emitting device of claim 1, wherein
the filler has a negative coefficient of thermal expansion.

3. The light emitting device of claim 1, further comprising:
an optical film opposed to the mounting area; and
an adhesive layer bonding the optical film to the sealing layer.

4. The light emitting device of claim 1, wherein
a coefficient of thermal expansion of the sealing layer containing the base material and the filler is 10×10\hat{ }-6 [1/K] or less.

5. The light emitting device of claim 1, wherein
an outer edge shape of the mounting area includes a corner portion,
the sealing layer includes a first portion covering an area excluding the corner portion in the mounting area, and a second portion covering an area including the corner portion in the mounting area, and
a density of the filler in the second portion is higher than a density of the filler in the first portion.

6. The light emitting device of claim 1, wherein
an outer edge shape of the mounting area includes a corner portion,
the sealing layer includes a first portion covering an area excluding the corner portion in the mounting area, and a second portion covering an area including the corner portion in the mounting area, and
the filler in the second portion is formed of a material having a larger difference in refractive index from the base material than a material of the filler in the first portion.

7. The light emitting device of claim 1, wherein
an outer edge shape of the mounting area includes a recess portion,
the sealing layer includes a first portion covering an area excluding the recess portion in the mounting area, and a third portion covering an area including the recess portion in the mounting area, and
a density of the filler in the third portion is higher than a density of the filler in the first portion.

8. The light emitting device of claim 1, wherein
an outer edge shape of the mounting area includes a recess portion,
the sealing layer includes e first portion covering an area excluding the recess portion in the mounting area, and a third portion covering an area including the recess: portion in the mounting area, and
the filler in the third portion is formed of a material having a larger difference in refractive index from the base material than a material of the filler in the first portion.

9. A display device comprising:
the light emitting device of claim 1; and
a display panel including a display area opposed to the mounting area of the light emitting device.

10. The display device of claim 9, wherein
the light emitting device and the display panel are bent, such that the mounting area and the display area have curvatures.
